(19) United States
(12) Patent Application Publication
(10) Pub. No.: US 2020/0069015 A1
(43) Pub. Date: Mar. 5, 2020

(54) WATER RESISTANT PROTECTIVE CASE FOR PORTABLE ELECTRONIC DEVICE

(71) Applicant: Griffin Technology, LLC, Irvine, CA (US)

(72) Inventors: Daniel Poon, Nashville, TN (US); Jeff Fielder, Sarasota, FL (US); Aaron Jones, Nashville, TN (US)

(73) Assignee: Griffin Technology, LLC, Irvine, CA (US)

(21) Appl. No.: 16/559,621

(22) Filed: Sep. 3, 2019

Related U.S. Application Data
(63) Continuation-in-part of application No. 15/990,438, filed on May 25, 2018, now Pat. No. 10,398,205.
Application No. 15/990,438 is a continuation of application No. 15/605,655, filed on May 25, 2017, now Pat. No. 9,980,544.
Application No. 15/605,655 is a continuation of application No. 14/720,476, filed on May 22, 2015, now Pat. No. 9,668,555.
(60) Provisional application No. 62/001,638, filed on May 22, 2014.

(51) Int. Cl. A45C 11/00; A45C 13/00; H04B 1/3888

(52) U.S. Cl. CPC A45C 11/00; A45C 13/008; H04B 2001/3894; H05K 999/99; A45C 2011/002; H04B 1/3888

(57) ABSTRACT

A water resistant device case including a front and back assembly that mate to enclose an electronic device is disclosed herein. The front assembly includes a rigid front frame, a touch screen cover bonded thereto, an inner bumper attached thereto, and an elastomeric main seal attached around a periphery thereof. The back assembly includes a rigid back frame, an elastomeric over mold formed on an exterior thereof, and an inner bumper attached thereto. A snap tab attached to the back frame mates with a snap hook on the front assembly to hold the front and back assemblies together when the device is enclosed within the case. A main water resistant seal and a secondary water resistant seal are formed around a perimeter of the front and back assemblies. A closed cell foam is used to seal apertures associated with the device's audio inputs and outputs.

### CROSS-REFERENCE TO RELATED APPLICATIONS

This application is a continuation-in-part of U.S. patent application Ser. No. 15/990,438, filed on May 25, 2018 and issuing as U.S. Pat. No. 10,398,205, which is a continuation of U.S. patent application Ser. No. 15/605,655, filed on May 25, 2017 and issued as U.S. Pat. No. 9,980,544, which is a continuation of U.S. patent application Ser. No. 14/720,476, filed on May 22, 2015 and issued as U.S. Pat. No. 9,668,555, which claims the benefit of and priority to U.S. Provisional Patent Application Ser. No. 62/001,638, filed on May 22, 2014, the entireties of which are hereby incorporated herein by reference.

### BACKGROUND

A wide variety of protective device cases that provide various levels of protection and water resistance for the enclosed device have been disclosed. One issue with known protective device cases is that increased durability, water resistance, and protection typically corresponds to increased difficulty in accessing the enclosed device. In addition, many known device cases do not allow a user easy access to the various controls and features of the protected device or fail to adequately protect the controls of the device. These problems are magnified for small touch screen devices that are very sensitive, have a limited display area, and may require cleaning.

Thus, there remains an unmet need for an improved device case that provides a high degree of protection and water resistance to an enclosed device while allowing easy access to the screen and controls of the enclosed device.

### SUMMARY

A water resistant device case adapted to enclose a portable electronic device is disclosed herein. The device case includes a front assembly constructed from a rigid front frame. A touch screen cover is bonded to the front frame, where the touch screen cover allows a touch screen of the portable electronic device to be used when the portable electronic device is enclosed within the device case. An elastomeric inner bumper is attached to the front frame to provide padding for the enclosed device. An elastomeric main seal is attached around a periphery of the front frame. A front assembly fastener, preferably a snap hook, is attached to the front frame. The front frame may preferably be formed from a rigid plastic material.

The front assembly mates with a back assembly. The back assembly includes a rigid back frame. An elastomeric over mold is formed on an exterior of the back frame and an elastomeric inner bumper is attached to an interior surface of the back frame. A back assembly fastener, preferably a snap tab, attached to the back frame mates with the front assembly fastener to hold the front assembly and the back assembly together when the portable electronic device is enclosed within the device case. The back frame may preferably be formed from a rigid plastic material.

A main seal is formed around a perimeter of the front and back assembly by the elastomeric main seal on the front assembly being held against an inner surface of the back frame by the fastening members on the front and back assemblies. A secondary seal is formed around a perimeter of the front and back assembly by the front assembly being held against the back assembly by the fastening members on the front and back assemblies. The secondary seal may be formed by an elastomeric secondary sealing member attached around a periphery of the front frame that mates with an exterior surface of the back assembly to form the secondary seal. Alternatively, the secondary seal may be formed between a surface of the front frame and a sealing protrusion positioned on a portion of the elastomeric over mold that extends over an upper edge of the back frame.

The front and back assemblies include apertures corresponding to the audio inputs and outputs of the electronic device that are covered and sealed by a closed cell foam. The front and back assemblies also include apertures corresponding to a port of the portable electronic device and a removable elastomeric port cover that removably covers the apertures. The removable elastomeric port cover includes an attachment protrusion that creates a compression fit between the elastomeric cover and an exterior of the device case that seals the port apertures.

### BRIEF DESCRIPTION OF THE DRAWINGS

FIG. 1 is an illustration of an embodiment of the disclosed device case.

FIGS. 2A-2C are respectively illustrations of the seal of the device case of FIG. 1 in the opened, closing, and closed positions.

FIG. 3 is an illustration of an alternative secondary seal construction for an embodiment of the disclosed device case.

FIG. 4 is an illustration of closed cell foam film seals for an embodiment of the disclosed device case.

FIG. 5 is an illustration of an elastomeric bottom cover for an embodiment of the disclosed device case.

### DETAILED DESCRIPTION

A water resistant device case that includes a front and back assembly that mate to enclose an electronic device is disclosed herein. The front assembly includes a rigid front frame, a touch screen cover bonded to the front frame, an inner bumper attached to the front frame, and an elastomeric main seal attached around a periphery of the front frame. The back assembly includes a rigid back frame, an elastomeric over mold formed on an exterior of the back frame, and an inner bumper attached to the back frame. A snap tab attached to the back frame mates with a snap hook on the front assembly to hold the front and back assemblies together when the device is enclosed within the case. A main water resistant seal is formed around a perimeter of the front and back assemblies by the elastomeric main seal on the front assembly being held against an inner surface of the rigid back frame. A secondary water resistant seal is formed around a perimeter of the front and back assemblies by an elastomeric secondary sealing member attached around a periphery of the front frame that mates with an exterior surface of the back assembly to form a secondary water resistant seal. A closed cell foam is used to seal apertures associated with the device's audio inputs and outputs.

The device case includes a front assembly constructed from a rigid front frame. A touch screen cover is bonded to the front frame, where the touch screen cover allows a touch screen of the portable electronic device to be used when the portable electronic device is enclosed within the device case. An elastomeric inner bumper is attached to the front frame to provide padding for the enclosed device. An elastomeric main seal is attached around a periphery of the front frame. A front assembly fastener, preferably a snap hook, is attached to the front frame. The front frame may preferably be formed from a rigid plastic material.

The front assembly mates with a back assembly. The back assembly includes a rigid back frame. An elastomeric over mold is formed on an exterior of the back frame and an elastomeric inner bumper is attached to an interior surface of the back frame. A back assembly fastener, preferably a snap tab, attached to the back frame mates with the front assembly fastener to hold the front assembly and the back assembly together when the portable electronic device is enclosed within the device case. The back frame may preferably be formed from a rigid plastic material.

A main seal is formed around a perimeter of the front and back assembly by the elastomeric main seal on the front assembly being held against an inner surface of the back frame by the fastening members on the front and back assemblies. A secondary seal is formed around a perimeter of the front and back assembly by the front assembly being held against the back assembly by the fastening members on the front and back assemblies. The secondary seal may be formed by an elastomeric secondary sealing member attached around a periphery of the front frame that mates with an exterior surface of the back assembly to form the secondary seal. Alternatively, the secondary seal may be formed between a surface of the front frame and a sealing protrusion positioned on a portion of the elastomeric over mold that extends over an upper edge of the back frame.

The front and back assemblies include apertures corresponding to the audio inputs and outputs of the electronic device that are covered and sealed by a closed cell foam. The front and back assemblies also include apertures corresponding to a port of the portable electronic device and a removable elastomeric port cover that removably covers the apertures. The removable elastomeric port cover includes an attachment protrusion that creates a compression fit between the elastomeric cover and an exterior of the device case that seals the port apertures.

In some embodiments, the disclosed case includes a front or top assembly having a transparent, conductive screen film that covers, and allows a user to operate, the touch screen of the enclosed electronic device. The front assembly may include a rigid frame that encloses the screen film. The rigid frame may preferably be plastic, more preferably polycarbonate. The rigid frame may extend in a direction substantially perpendicular to the surface of the screen film to form a wall around the periphery of the front assembly. The screen film and wall may include apertures with seals which correspond to, and provide access to, components and controls of the enclosed electronic device. The seals may preferably be made from a soft elastomeric material such as rubber, and may include button portions that allow the operation of corresponding buttons on the electronic device enclosed within the case.

Apertures corresponding to, e.g., an earpiece, speaker, microphone, and home button of an enclosed electronic device may be provided in the front assembly. Each aperture may be closed with a corresponding film, preferably a closed cell foam, that is bonded to the inside of the front assembly that faces the enclosed electronic device.

The front assembly mates with a back or bottom assembly to enclose the electronic device. The bottom assembly may include a rigid frame which may be partially encased by a soft rubber over mold and/or rubber layer. The rigid frame may preferably be plastic, more preferably polycarbonate. The bottom assembly may also include a bottom surface and curved sidewalls that extend from the bottom surface. Various portions of the bottom assembly may be covered by a soft rubber material.

The front assembly may be joined to the bottom assembly by fasteners, such as by engagement of one or more snap hooks with corresponding snap tabs on the bottom assembly, to enclose the device. Water resistance may be provided by both a main seal and a secondary seal formed between sealing members on the front and back assemblies.

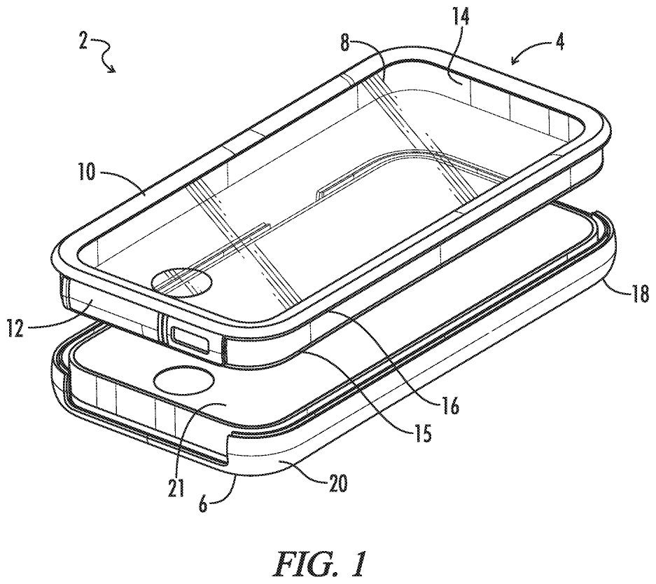

FIG. 1 shows an illustration of an embodiment of the disclosed device case. Although a case for a particular device is shown, ordinarily skilled artisans will understand that the disclosed device case may readily be adapted for a wide variety of different devices. The device case 2 has two primary components, a front cover 4 and a back cover 6.

The front cover 4 includes a screen film 8 that covers the device touchscreen and allows the touchscreen to be used while the device is enclosed within the case 2. The screen film 8 is mounted on a relatively hard and rigid plastic base 10, preferably constructed from a rigid polycarbonate plastic. An elastomeric bottom cover 12, elastomeric inner bumper 14, main elastomeric sealing member 15, and secondary elastomeric sealing member 16 are also mounted on the polycarbonate plastic base 10 of the top cover 4.

The back cover 6 also includes a relatively hard and rigid polycarbonate plastic base 18. The back cover base 18 has an elastomeric outer surface 20 created from a rubber over mold and an elastomeric inner surface 21. The elastomeric components provide padding and shock absorption for the enclosed device while the polycarbonate components improve the rigidity and strength of the case.

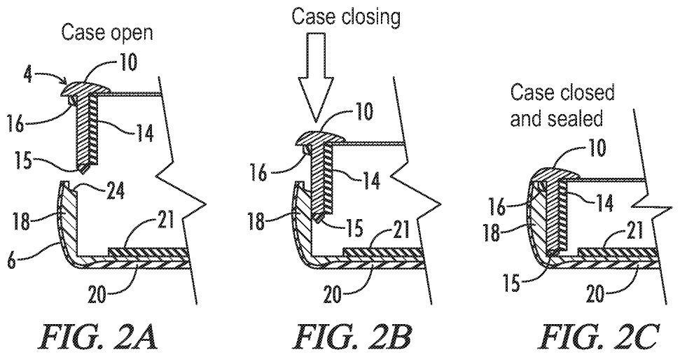

Water resistance is provided by both the main seal 15 and the secondary seal 16. FIGS. 2A-2C show illustrations of the seal of the case of FIG. 1 in the opened (FIG. 2A), closing (FIG. 2B), and closed (FIG. 2C) positions. The main seal is formed through the compression of the main sealing member 15 against the rigid polycarbonate base 18 of the back cover 6. The secondary seal is formed through the interaction of the elastomeric secondary sealing member 16 and a corresponding depression 24 in the upper edge of the polycarbonate base 18 which forms a water resistant seal around the periphery of the front and back covers.

The case is closed by pressing on the base 10 of the front cover 4 to insert the front cover 4 over the device and into the cavity of the back cover 6 as shown in FIG. 2B. Once the front cover 4 is fully inserted into the back cover 6 as shown in FIG. 2C, the elastomeric main and secondary sealing members 15 and 16 of the front cover 4 are engaged with the rigid poly carbonate base 18 of the back cover to form a pair of water resistant seals around the perimeter of the device case.

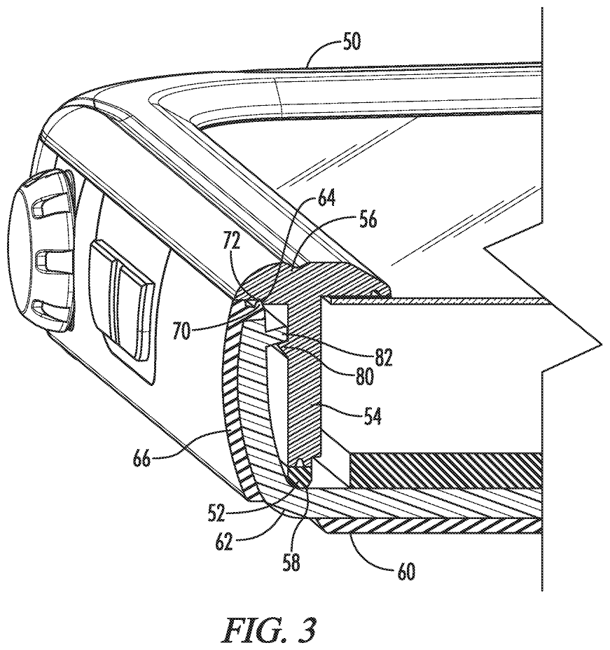

FIG. 3 shows an alternative main and secondary seal arrangement for an embodiment of the disclosed device case. In the embodiment shown, the front assembly 50 has a soft, elastomeric compression main or primary seal 52 at or near the bottom of the side walls 54 which extend from the plastic frame 56 of the front assembly for engagement with the inner bottom surface 58 of the bottom assembly 60. When the front and bottom assemblies 50 and 60 engage, the compression seal 52 is compressed against the hard plastic bottom frame 62 to form a primary water resistant seal. A secondary swipe seal 64 is formed at the top of the plastic bottom frame 62 between the bottom rubber over mold 66 and front rigid frame 56. The bottom over mold 66 extends inward over the rigid plastic bottom frame 62 and has a vertical protrusion 70 formed thereon. When assembled, the vertical protrusion 70 contacts a flanged inner surface 72 of the front rigid frame 68 to form the swipe seal 64.

The primary and secondary seals 52 and 64 are formed upon closing and locking the case. This is accomplished by frictional engagement of the snap hooks 80 on the front assembly with corresponding snap tabs 82 on the bottom assembly. The snap hooks 80 and snap tabs 82 are shaped to force the plastic bottom frame 62, including the snap tabs 82, initially outward as the front and bottom assemblies 50 and 60 are joined and the snap hooks 80 and snap tabs 82 come into contact. As this occurs, the swipe seal 64 commensurately flexes outward with the plastic bottom frame 62. As the front and bottom assemblies 50 and 60 continue closing together, the snap hooks 80 from the front assembly pass to a position below the snap tabs 82, allowing the plastic bottom frame 62, snap tabs 82, and swipe seal 64 to return to their original positions.

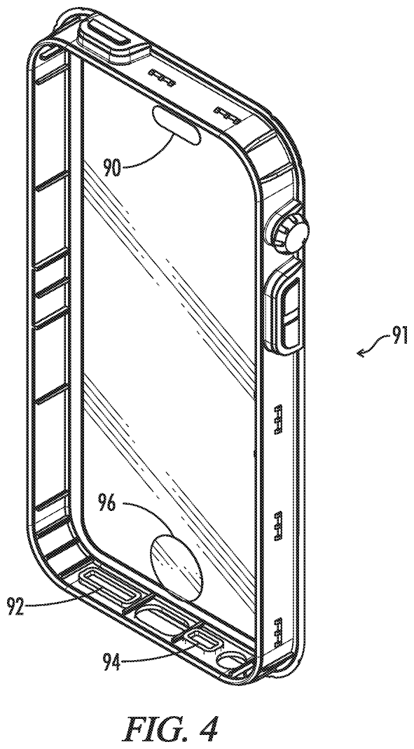

FIG. 4 shows an illustration of the apertures and protective covers of the front assembly 91 of an embodiment of the disclosed device case. Apertures corresponding to, e.g., an earpiece 90, speaker 92, microphone 94, and home button 96 of an enclosed electronic device are provided in the front assembly 91. Corresponding apertures, not shown, are found on the back assembly so that access to the components of the device through the exterior of the case is possible when the front assembly 91 is mated to the back assembly. Each aperture 90, 92, 94, and 96 on the front assembly 91 is closed with a correspondingly shaped film that is bonded to the inside of the front assembly 91 that faces the enclosed electronic device. The film covering the audio apertures 90, 92, and 94 is preferably a closed cell foam that allows sound to readily pass through the film while providing water resistance.

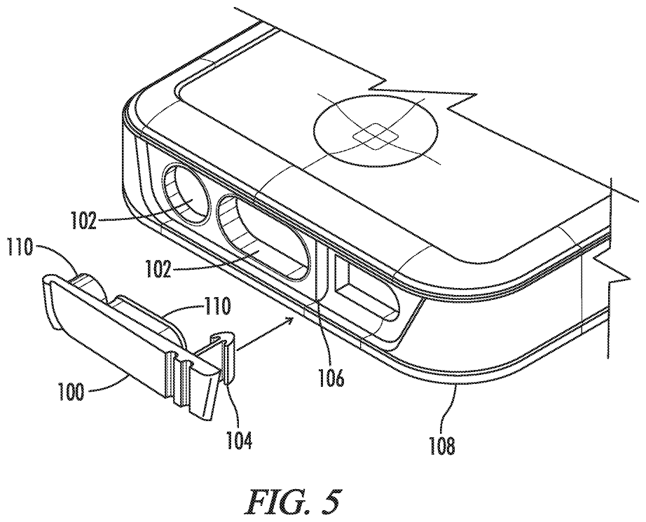

FIG. 5 shows a removable elastomeric cover 100 for the charging and data cable attachment ports of the enclosed device. Apertures 102 are provided through the case assembly 108 such that the ports of the device are exposed. The removable elastomeric cover 100 has plugs 110 that fit into the apertures 102 when the cover 100 is attached to the case assembly 108. A protrusion 104 on the cover is adapted to be inserted into a corresponding slot 106 in the case assembly 108 to removably secure the cover 100 to the case assembly. The protrusion 104 is shaped such that the elastomeric cover 100 is compressed against the case assembly 108 when the cover 100 is attached to the case assembly 108, thereby sealing the apertures 102 in a water resistant manner.

The examples above are intended as illustrative and are not intended to limit or otherwise restrict the invention. Although particular embodiments have been described herein, it is not intended that such references be construed as limitations upon the scope of the invention except as set forth in the following claims. All references cited herein are expressly incorporated by reference.

What is claimed is:

1. A water resistant protective case configured to enclose a portable electronic device comprising:
a front assembly comprising a rigid front frame having an external facing top surface and an opposing bottom end, a touch screen cover bonded to the front frame, an elastomeric main seal attached around a periphery at the bottom end of the front frame, and a front assembly fastener attached to the front frame; and
a back assembly comprising a rigid back frame, an elastomeric over mold formed on an exterior of the back frame, and a back assembly fastener attached to the back frame that mates with the front assembly fastener to hold the front assembly and the back assembly together,
wherein a main seal is formed around a perimeter of the front and back assemblies by the elastomeric main seal on the front assembly being held against an inner surface of the rigid back frame,
wherein a secondary seal is formed around a perimeter of the front and back assemblies by the front assembly fastener and the back assembly fastener by the front assembly being held against the back assembly, and
wherein the elastomeric over mold extends over an upper edge of the rigid back frame and has a sealing protrusion positioned on the upper edge of the rigid back frame.
